(19) United States
(12) Patent Application Publication
(10) Pub. No.: US 2007/0096127 A1
(43) Pub. Date: May 3, 2007

(54) Semiconductor micro-cavity light emitting diode

(76) Inventors: P. Morgan Pattison, Morgantown, WV (US); Rajat Sharma, Goleta, CA (US); Steven P. DenBaars, Goleta, CA (US); Shuji Nakamura, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(21) Appl. No.: 11/510,240

(22) Filed: Aug. 25, 2006

Related U.S. Application Data
(60) Provisional application No. 60/711,940, filed on Aug. 26, 2005.

(51) Int. Cl. H01L 33/00

(52) U.S. Cl. 257/98

(57) ABSTRACT

A spontaneously light emitting nitride-based active region placed within a micro-cavity bounded by a first mirror and a second mirror, wherein the micro-cavity has been thinned to a resonant thickness within a micro-cavity regime.

### CROSS-REFERENCE TO RELATED APPLICATIONS

This application claims the benefit under 35 U.S.C. Section 119(e) of the following co-pending and commonly-assigned U.S. patent application:

U.S. Provisional Patent Application Ser. No. 60/711,940, filed on Aug. 26, 2005, by P. Morgan Pattison, Rajat Sharma, Steven P. DenBaars and Shuji Nakamura, entitled “SEMICONDUCTOR MICRO-CAVITY LIGHT EMITTING DIODE”, attorneys docket number 30794.146-US-P1 (2006-017-1);

which application is incorporated by reference herein.

This application is related to the following co-pending and commonly-assigned applications:

U.S. Utility application Ser. No. 11/067,956, filed on Feb. 28, 2005, by Claude C. A. Weisbuch, Aurelien J. F. David, and Steven P. DenBaars, entitled “HIGH EFFICIENCY LIGHT EMITTING DIODE (LED) WITH OPTIMIZED PHOTONIC CRYSTAL EXTRACTOR,” attorneys' docket number 30794.126-US-01 (2005-198-1);

U.S. Utility application Ser. No. 11/403,288, filed on Apr. 13, 2005, by James S. Speck, Benjamin A. Haskell, P. Morgan Pattison and Troy J. Baker entitled “ETCHING TECHNIQUE FOR THE FABRICATION OF THIN (Al, In, Ga)N LAYERS” attorneys' docket number 30794.132-US-U1 (2005-509);

which applications are incorporated by reference herein.

### BACKGROUND OF THE INVENTION

1. Field of the Invention

The invention is related to semiconductor micro-cavity light emitting diodes (MCLEDs).

2. Description of the Related Art

(Note: This application references a number of different publications as indicated throughout the specification by one or more reference numbers within parentheses, e.g., (Ref. x). A list of these different publications ordered according to these reference numbers can be found below in the section entitled “References.” Each of these publications is incorporated by reference herein.)

The current state-of-the-art of nitride-based light emitters comprises two distinct families of devices: high brightness light emitting diodes (LEDs) and laser diodes (LDs). Gallium nitride-based LEDs hold the promise of revolutionizing the lighting industry, thanks to their high efficiency and versatility. Similarly, gallium nitride-based LDs have already had a significant impact on high-density data storage.

Standard nitride-based LEDs are typically fabricated from epitaxial material grown by metal organic chemical vapor deposition (MOCVD). FIG. 1 is a schematic of a conventional nitride based LED. The epitaxial LED material typically is comprised of a Si-doped (n-type) GaN layer (101) grown on a suitable substrate material (102) such as sapphire or silicon carbide. The next layer is an active region (103) with a single-quantum-well or multiple-quantum-well structure emitting green, blue, or near-ultraviolet (UV) light. In this example, the active region is comprised of several (5-10) (In, Ga)N quantum wells separated by thick GaN or (In, Ga)N barriers. The total thickness of the active region is typically at least 100 nm, and can be much thicker. Finally, on top of the active region (103), a Mg-doped (p-type) GaN (104) is grown. The typical total thickness of a standard LED structure is at least 4 microns (Ref. 3). This epitaxial material is processed into an LED through the formation of p-type (105) and n-type (106) electrical contacts onto the p-type and n-type layers to enable electrical current to be injected into the device. The device may also comprise a semi-transparent electrode (107).

This standard LED is typically converted into a high brightness LED by one of two techniques. The first technique is chip shaping, wherein the substrate material is shaped to maximize light extraction (Ref. 4). By shaping the substrate that the epitaxial material is grown on, more of the generated light that is typically lost to total internal reflection is directed out of the LED, thereby improving extraction efficiency.

The second technique to improve brightness of a standard LED is to deposit a highly reflective mirror material on the surface and collect the light from the substrate side of the LED, if the substrate is transparent (Ref. 5). With this technique, all of the light emitted downward, which is typically lost, can be reflected back towards the surface and extracted from the LED.

These performance enhancing features may be used together to maximize extraction efficiency. While these techniques enhance extraction efficiency they do not confine the light to discrete cavity modes.

Laser diodes operate on an entirely different principle than LEDs. While the light in LEDs is generated through spontaneous emission, lasers use stimulated emission to efficiently generate light that is extremely spectrally pure and directional (Ref. 3).

Laser diodes have an epitaxial structure similar to the standard LED structure, but have additional layers inserted to confine the light to the emitting region in order to maximize the stimulated emission. These additional layers greatly increase the complexity of the epitaxial growth for laser diodes. The epitaxial material also requires substantially more processing in order to fabricate the laser diodes.

Another characteristic of laser diodes is that the light is emitted parallel to the substrate, which can cause difficulties with implementation of these devices. In order to direct the light vertically, the chip must be placed on its side which can further complicate the design of an optical system. The additional complexity of the material growth and processing of the laser diodes results in these devices having a higher cost.

One application of these devices is for lighting. The light emitted by these devices may be used to excite a phosphor or combination of phosphors to produce secondary emission in the green/red/yellow range of the color spectrum, as in a “white” light emitting diode.

Another very important application for gallium nitride based light sources is as excitation sources for materials that have an absorption edge close to the GaN or [Al, In, Ga]N band-edge. For example, a GaN ultraviolet light emitting diode could be used as an excitation source to detect biological agents that would absorb the light and then re-emit light at a characteristic wavelength. This absorption and re-emission would thus mark the presence of a specific biological agent.

Another recent application of GaN based light sources is as light sources for plastic optical fiber communication systems.

As described in U.S. Pat. No. 5,226,053 (Ref. 1), when an LED is placed within a Fabry-Perot optical cavity defined by a highly reflective mirror on one side and a less reflective mirror on the other, the emission of light from the active region is restricted to specific modes of the optical cavity. This leads to enhancements in directionality and light extraction efficiency, as well as spectral narrowing, and, in specific cases, improvements in quantum efficiency. Optical devices of this type are known as a resonant cavity light emitting diodes (RCLEDs).

Nitride-based RCLEDs (Ref. 6) have been demonstrated, but are not generally produced. The limited benefits of the RCLED are offset by the complicated processing necessary to fabricate these devices.

The present invention describes a device that may be considered a type of RCLED, and is known as a Micro-Cavity Light Emitting Diode (MCLED). The advantages of the MCLED stem from the confinement of the spontaneously emitted light into cavity modes. All of the benefits of RCLEDs are further enhanced when the length of the cavity, defined by the mirrors, is reduced, and, at a certain point, the device enters a “micro-cavity” regime (Ref. 2).

The “micro-cavity” regime is defined as the critical thickness below which the cavity order, m_{c}, is less than 2×n², where n is the index of refraction of the emitting material. The cavity order, m_{c}, is defined as [2nL_{c}/λ] rounded to the closest integer, where L_{c} is the length of the cavity and λ is the wavelength of emitted light in air. The fundamental premise of the present invention is a nitride LED that is in a cavity with a cavity length short enough for the device to be in the micro-cavity regime for the nitride material system.

MCLEDs possess superior light extraction efficiency, improved spectral purity, and improved directionality of emission, as compared to conventional LEDs and RCLEDs. The enhanced performance of the MCLED should make the nitride-based MCLED much more promising for widespread use. The utility of nitride based MCLEDs will be in applications where performance requirements are too strict for LEDs but where the performance and cost of laser diodes are not necessary.

What is needed are improved methods for the fabrication of nitride based MCLEDs through innovative device design and material growth, as well as advanced nitride processing and fabrication steps. The present invention satisfies these needs.

### SUMMARY OF THE INVENTION

The present invention discloses a micro-cavity light emitting diode (MCLED), comprising a spontaneously light emitting nitride-based active region placed within a micro-cavity bounded by a first mirror and a second mirror, wherein the micro-cavity has been thinned to a resonant thickness within a micro-cavity regime. The resonant thickness may be a micro-cavity length L_{c} satisfying a resonance requirement approximately equal to an integral multiple of half-wavelengths of light emitted by the nitride based active region, such that: L_{c}≈m_{c}×λ/2n. The micro-cavity length can be slightly reduced from the resonance requirement in order to detune the cavity so the micro-cavity will be in resonance with emitted light only when the light is emitted at an angle off of the normal (90°) and the angle is within a critical angle for light emission for the MCLED.

The nitride based active region may be placed, with respect to the first or second mirror, at an anti-node of an optical wave within the micro-cavity. The active region may be less than λ/4n thick to allow for the entire active region to be located at an anti-node of a standing wave within the micro-cavity. The nitride-based active region may be a compound active region consisting of localized active regions located on adjacent anti-nodes of a standing optical wave.

The MCLED may further comprise n-type gallium nitride (GaN) and p-type GaN bounded by the first and second mirrors. The p-type GaN thickness may locate the active region on an anti-node of the standing optical wave.

The first mirror may comprise a highly reflective metal mirror at one end of the micro-cavity that makes good electrical contact with the n-GaN and the second mirror may comprise an interfacial mirror at another end of the cavity. Alternatively, a single distributed Bragg reflector may be used for the first or second mirror.

The MCLED may further comprise a current confinement layer which may be an ion implantation layer.

### BRIEF DESCRIPTION OF THE DRAWINGS

Referring now to the drawings in which like reference numbers represent corresponding parts throughout:

FIG. 1 is a schematic diagram of a standard LED structure;

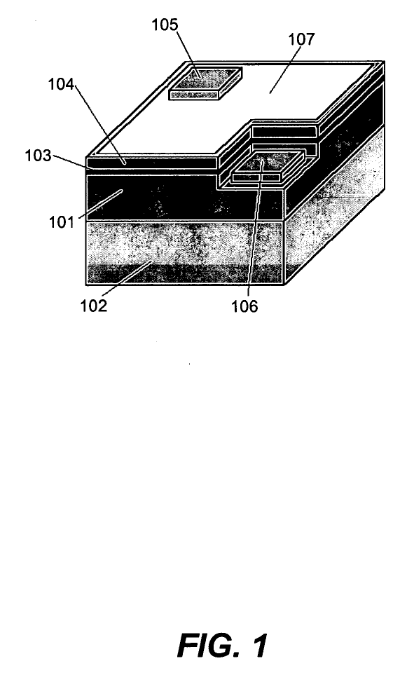

FIG. 2(a) illustrates a resonant micro-cavity, FIG. 2(b) illustrates a resonant cavity, and FIG. 2(c) illustrates a detuned resonant micro-cavity;

FIG. 3 illustrates constructive interference;

FIG. 4 illustrates active region placement;

FIG. 5 illustrates a typical nitride-based MCLED growth structure;

FIG. 6 is a flow chart of the processing steps performed according to the preferred embodiment of the present invention;

FIG. 7 is a schematic of a device fabricated according to the present invention; and

FIG. 8 is the emission spectra of processed LED and MCLED from the same growth material.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The general purpose of the nitride-based MCLED described herein is as a high efficiency, high spectral purity, and high directionality light emitter of wavelengths from UV to green. The light emitted by a MCLED is more spectrally pure and is more directional than the light from a standard LED. Also, a MCLED has higher efficiency than a standard LED.

With all of these advantages, MCLEDs are the natural choice for applications where superior performance than a LED is required, but the high cost and extreme performance of a laser diode are not necessary. Some examples of suitable applications have been mentioned previously, high efficiency light emitters, optical excitation sources, and light sources for fiber optic data transmission.

Technical Description

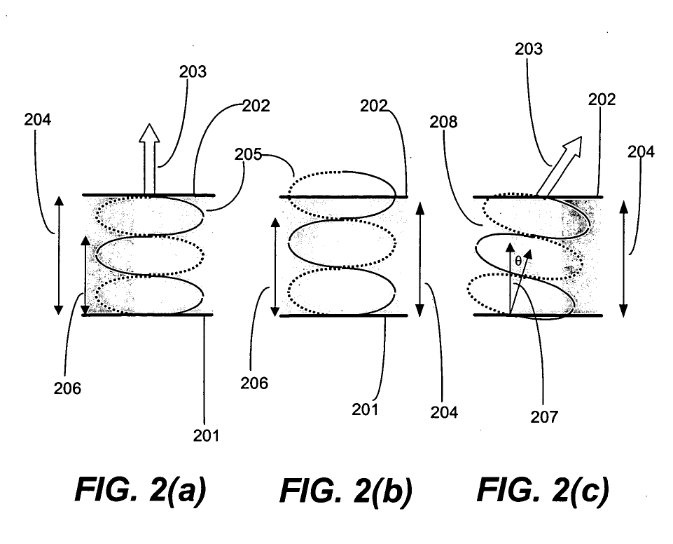

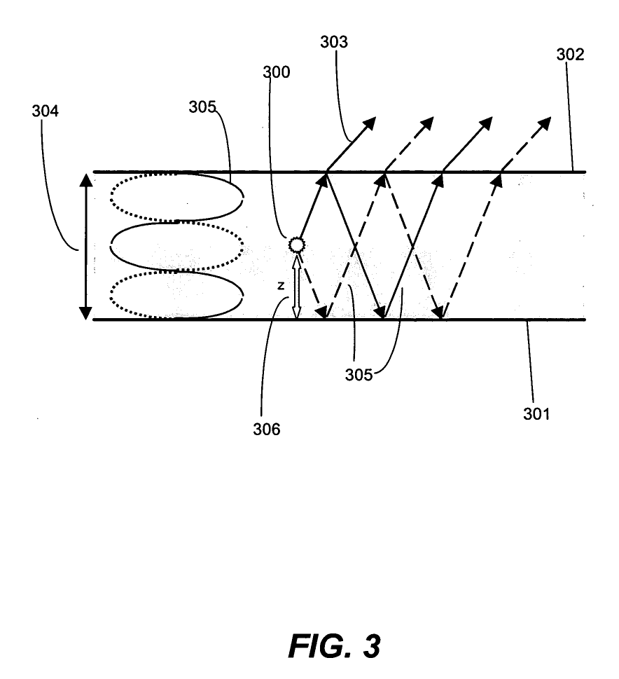

FIGS. 2(a), 2(b), 2(c) and FIG. 3 illustrate that a micro-cavity light emitting diode is essentially a spontaneously light emitting nitride-based active region (300) placed within a micro-cavity bound by two mirrors, for example a first mirror (201), (301) and a second mirror (202), (302), wherein the micro-cavity has a resonant thickness within a micro-cavity regime.

In the design outlined herein, the mirrors used are a highly reflective metal mirror (201), (301) at one end of the cavity and the GaN/air interface at the other end (202), (302). In a typical micro-cavity LED, the metal mirror may have a reflectivity of 50-100%, while the interfacial mirror has a reflectivity of approximately 20%, in the case of a GaN/air interface. Light (203), (303) may be extracted at the end with the interfacial mirror.

The micro-cavity may be considered within the micro-cavity regime if the resonant thickness (204), (304) has a dimension L_{c} such that m_{c}<2×n², where m_{c} is the cavity order defined as an integer multiplied by [2nL_{c}/λ], n is the index of refraction for the nitride-based material at that wavelength λ, and L_{c} is the micro-cavity length. For λ=490 nm, the index of refraction of GaN is approximately n=2.4. The micro-cavity regime for this device would be when the cavity is 1176 nm or smaller. Similarly, for a different nitride device that emits at 420 nm and has an index of refraction at that wavelength of approximately n=2.49, the cavity length would need to be less than 1046 nm in order for the device to operate in the micro-cavity regime.

FIG. 2(a) and FIG. 3 also show that not only does the micro-cavity need to be short enough to operate within the micro-cavity regime, but the micro-cavity length (204), (304) must also satisfy a resonance requirement approximately equal to an integral multiple of half-wavelengths of the light emitted (205), (305) by the active region (300) in the semiconductor material. The cavity length (or resonant thickness) L_{c} (204), (304) is L_{c}=m_{c}×λ/2n, where m_{c} is an integer called the cavity order, λ is the wavelength of the emitted light in air, n is the index of refraction of the emitting material, and λ/n is the wavelength in the semiconductor material (206). In FIG. 2(a), L_{c}=3×λ/2n (m_{c}=3). FIG. 3 shows how light (305) emitted by the active region (300) constructively interferes if the cavity length (304) approximately satisfies the condition L_{c}=m_{c}×λ/2n.

However, FIG. 2(c) shows how the cavity length (204) can be slightly different from the resonance requirement in order to detune the cavity. In this situation, the cavity will be in resonance with the emitted light only when the light is emitted at an angle (207) off of the normal (90°). However, the detuning must be designed such that the emission angle is within the critical angle for light emission for the MCLED, which may comprise a GaN-based material (208). The critical angle is defined as θ_{c}=sin⁻(nₑₓₜ/n_{GaN}), where θ_{c} is the critical angle (207), nₑₓₜ is the index of refraction for the medium that the device is emitting into such as air or epoxy, and n_{GaN} is the index of refraction of the emitting material (208), for example GaN. Light emitted at angles beyond the critical angle will be totally internally reflected within the device and cannot be extracted. Detuning the cavity enables a further enhancement of the extraction efficiency of the light (Ref. 2). In FIG. 2(c), the detuned resonance condition is L_{c}=3×(λ/2n)cos θ (m_{c}=3, θ is the critical angle (207)).

FIG. 3 also shows the active region (300) positioned at a distance z (306) from a mirror (301).

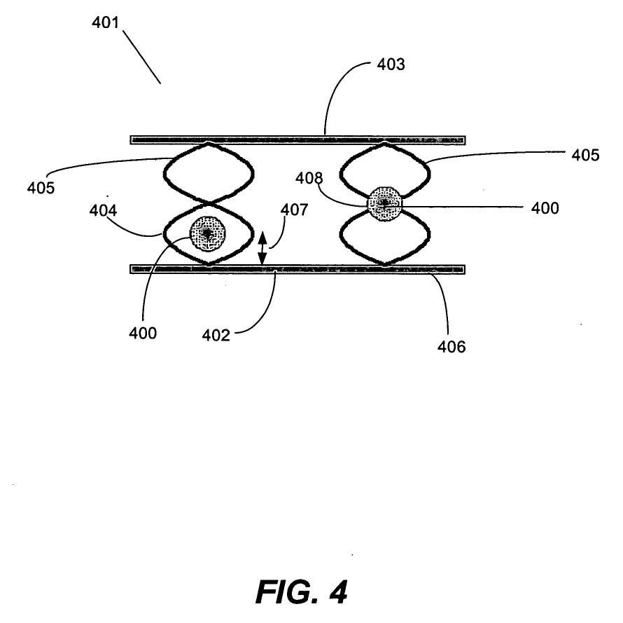

FIG. 4 shows the nitride-based active region (400) positioned at two different locations inside the micro-cavity (401), one of which is correct. The nitride based active region (400) must be placed with respect to the first mirror (402) or second mirror (403) at an anti-node (404) of the optical wave (405) within the micro-cavity (401). During the growth of the nitride-based MCLED epitaxial material, the active region (400) can be precisely located with respect to the top surface (406), which is where the first mirror (402) or metal mirror is eventually placed, so the distance (407) between the active region (400) and the metal mirror (402) may be accurately controlled. This distance (407) needs to be such that the active region (400) is at an anti-node of the standing wave, z_{AR}=(2 m_{AR}+1)/4n_{GaN}, where z_{AR} is the distance (407) of the active region (400) from the metal mirror (402), m_{AR} is an integral multiple starting at zero, and n_{GaN} is the index of refraction of GaN at the wavelength of the emitted light. This requirement ensures that the light emitted downward from the active region and reflected by the metal mirror is in phase with the light emitted upward from the active region.

In FIG. 4, the active region appropriately positioned at distance z_{AR} (407) from the top surface (406), at an anti-node (404) of the optical wave (405), leads to increased emission, whereas the active region positioned elsewhere, for example, at a node (408) of the optical standing wave (405), leads to inhibited emission from the MCLED.

By placing the LED within a cavity, light can only be emitted into certain available modes that are resonant with the cavity. The number of available modes is an equivalent definition of the cavity order. The number of these modes that are within the critical angle extraction cone of the material divided by the total number of modes will be approximately equal to the extraction efficiency of the device, ηₑₓₜ≈mₑₓₜ/m_{c}, where ηₑₓₜ is the extraction efficiency of the device, mₑₓₜ is the number of modes within the extraction cone, and m_{c} is the cavity order. When the cavity is thin enough so that there is only one mode within the extraction angle, mₑₓₜ==1, then the device is operating within the micro-cavity regime and the extraction efficiency will be η≈1/m_{c}. Proper design of the cavity thickness and the placement of the active region within the cavity will ensure the optimum performance of the MCLED device.

There are several benefits to operating a device within the micro-cavity regime. A GaN-based micro-cavity LED will have improved extraction efficiency compared to a standard LED or RCLED and the extraction efficiency will have an inverse relation to the cavity length, the shorter the cavity the higher the extraction efficiency. MCLEDs will also exhibit enhanced directionality due to the confinement of the emitted light into available cavity modes. Furthermore, the micro-cavity LED emission is generally more spectrally pure than the emission from a standard LED. All of these benefits can be realized with a suitably designed and properly fabricated GaN-based MCLED device.

Growth and Fabrication

A typical growth and fabrication sequence that yields the micro-cavity light emitting diode that is proposed in this disclosure is described below. It should be noted that variations in the growth technique, order of the processing steps, deposition techniques, and etch techniques can be made without affecting the design of the MCLED device.

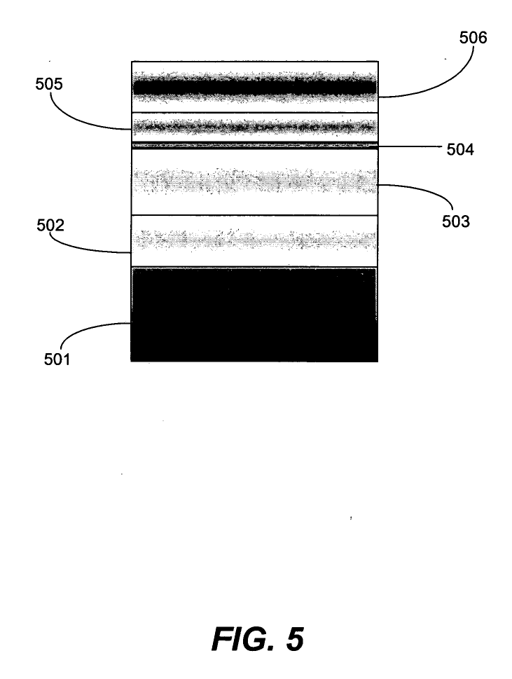

FIG. 5 is a schematic that illustrates the material growth and the various layers of the device. Note, however, that growth temperatures and growth rates are specific to the MOCVD tool, and thus are not provided. The preferred embodiment growth structure comprises:

1. The epitaxial crystal material grown by MOCVD on a c-plane sapphire substrate (501). In alternative embodiments, the epitaxial crystal may be grown by any crystal growth method such as MBE and HVPE, and on any substrate, for example, GaN, in any crystal orientation.

2. Unintentionally doped GaN layer (502). The first layer is unintentionally doped (UID) GaN that is approximately 2 microns thick. In alternative embodiments, this layer may be omitted.

3. Highly doped n-type layer (503). The next MOCVD grown layer is 2 microns of highly Si-doped GaN which acts as the n-type layer in the diode. The density of charge carriers is roughly ˜5×10¹⁸ per cubic centimeter. In alternative embodiments, this layer may be thicker or thinner.

4. Active region of the MCLED (504). The active region is comprised of 3 quantum wells 4 nm thick separated by GaN barriers 8 nm thick. The quantum wells are comprised of InGaN with an indium composition chosen for 480 nm light emission. The barriers are undoped GaN. In alternative embodiments, single quantum well or multiple quantum well active region with any thickness quantum wells and barriers may be grown as long as the active region can be localized to an anti-node of the standing optical wave. Additionally, the quantum wells may be grown to emit at any wavelength within the nitride wavelength range for alternative embodiments.

5. Mg doped AlGaN electron blocking layer (505). This layer is 20 nm thick.

6. Thin Mg-doped GaN layer (506). This layer acts as the p-type layer in the diode. The thickness of this layer is approximately 168 nm so that the active region (504) will be located on anti-node of the optical standing wave. Alternatively, any p-type GaN thickness that locates the active region on an anti-node of the standing optical wave may be used as long as the thickness of the cavity is such that the device is operating in the micro-cavity regime.

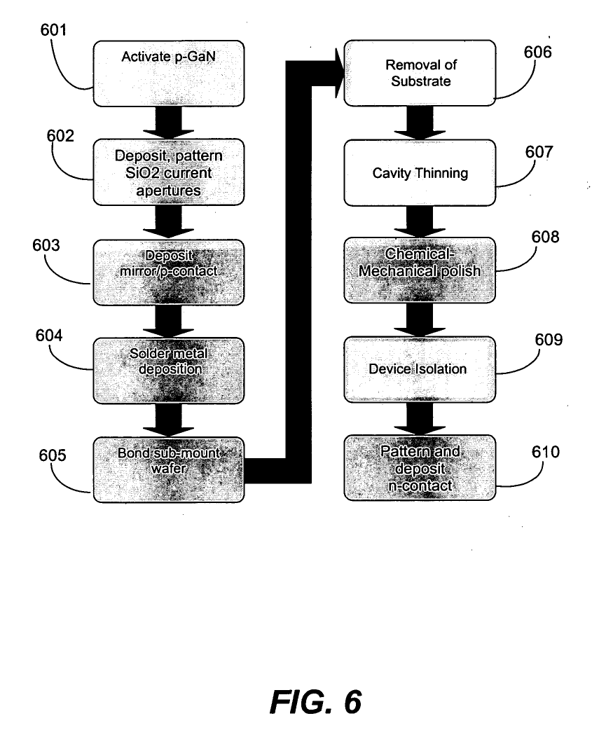

FIG. 6 is a flowchart illustrating the processing steps to fabricate an MCLED (grown, for example, according to FIG. 5) performed in the preferred embodiment of the present invention. Block 601 represents the step of activating the p-GaN. This comprises thermal activation of the Mg-doped layer to increase p-type GaN conductivity. The sample is heated to 700° C. for 15 minutes in an environment of N₂ and O₂.

Block 602 represents the step of depositing and patterning current apertures in SiO₂ to create a current confinement layer. The current can only enter the GaN through the aperture in the SiO₂, which limits the emission to the aperture region. The SiO₂ is deposited by plasma enhanced chemical vapor deposition (PECVD) at 250° C. on the p-GaN layer. A current aperture region may then be patterned in the SiO₂. An alternative current confinement scheme may utilize ion implantation of the p-GaN, n-GaN or active layer, or an alternative insulator instead of SiO₂. Alternative embodiments may use no current confinement layer or other current confinement configurations.

Block 603 represents the step of mirror and p-contact deposition. A silver mirror is deposited by electron beam deposition in the aperture region created in Block 602 to define one side of the cavity and act as the electrical contact to the p-type GaN. In alternative embodiments, any highly reflective metal mirror that makes a good contact with the p-doped GaN may be used for the mirror contact.

Block 604 represents the step of solder metal deposition. A blanket layer of solder metal consisting of 200 nm Sn and 1 μm Au is deposited by thermal evaporation on the current confinement layer of Block 602, as an adhesive layer that will attach the sub-mount carrier wafer to the sample.

Block 605 represents the step of sub-mounting by wafer bonding. A silicon wafer is bonded to the surface of the processed epitaxial material at the solder metal layer of Block 604 to provide mechanical support after the sapphire wafer is removed by laser lift-off. The bonding occurs under manual pressure at 285° C. In an alternative embodiment, the MCLED could be fabricated with a different sub-mount wafer in place of the silicon wafer.

Block 606 represents the step of laser lift-off of the substrate comprising the sapphire substrate being removed by dissociation of the gallium and nitrogen by laser excitation. The laser used is a KrF excimer laser with a pulse energy of 400 mJ. In alternative embodiments, the removal of the MCLED substrate may be achieved if the substrate is etched away with a reactive ion etch, etched away with a laser assisted wet etch, or removed by mechanical polishing, or other removal techniques.

Block 607 represents the step of cavity thinning using an etch. The cavity, comprising n-GaN, p-GaN and the active layer, is reduced from its original thickness of approximately 4 microns to 800 nm, corresponding to a cavity order of 8, by reactive ion etching. The reactive ion etching may be performed in a chlorine environment at a power of 150 watts for 45 minutes. In alternative embodiments, the cavity thinning step may use other techniques such as inductively coupled plasma etching, photo-electrochemical etching, chemical etching, or mechanical polishing. In alternative embodiments, the cavity maybe thinned to different thicknesses.

Block 608 represents the step of chemical mechanical polishing. The surface of the micro-cavity sample comprising the GaN/Air interface acting as a mirror is smoothed by polishing with silica slurry. The surface is smoothed to a roughness of 0.5-2.0 nm (RMS), as determined by atomic force microscopy. For polishing, a 0.02 μm colloidal silica slurry is used for 10 minutes at 50 rpm.

Block 609 represents the step of mesa formation. Mesas are patterned and defined on the surface of the sample to electrically isolate individual devices. The mesas are patterned by standard photolithography and etched by reactive ion etching. The sample is etched in a chlorine environment at a power 150 watts for 25 minutes. In alternative embodiments, other isolating techniques may be used.

Block 610 represents the step of n-contact deposition. The electrical contact to the n-doped GaN is defined by photolithography and then deposited by electron beam deposition on the n-GaN layer. The contact is typically comprised of Ti/Al/Ni/Au. A ring shaped contact is used to maximize the electrical efficiency of the device. In alternative embodiments, other metals and metal deposition techniques may be used.

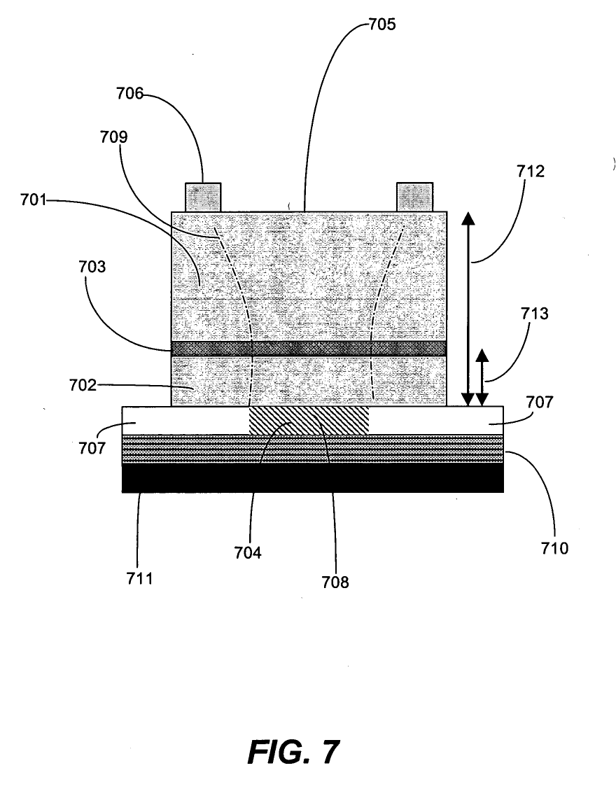

FIG. 7 is a schematic illustrating an MCLED comprising a spontaneously light emitting nitride-based active region placed within a micro-cavity bounded by a first mirror and a second mirror, wherein the micro-cavity has been thinned to a resonant thickness within a micro-cavity regime. The MCLED may be grown and fabricated, for example, using the method of FIG. 5 and FIG. 6 or otherwise.

The MCLED device of FIG. 7 comprises n-type GaN (701), p-type GaN (702), a nitride-based active region (703), all bounded by a first mirror (704) and a second mirror (705). The MCLED may further comprise at least one n-type contact (706) and a current confining scheme.

The current confining scheme may comprise, for example, a current confining layer (707) made from an insulator such as silicon dioxide (SiO₂), an aperture (708) in the current confining layer (707) and a highly reflective metal/conductor mirror deposited inside the aperture (708). The highly reflective metal mirror, for example silver, acts as a first mirror (704) at one end of the micro-cavity and also provides good electrical contact to the p-GaN (702). Alternatively, the current confinement scheme may comprise ion implanted p-GaN (702), n-GaN (701) or nitride-based active region (703). The current confinement scheme limits light emission (709) to the aperture region. The MCLED may further comprise solder metals (710) for wafer bonding the micro-cavity to a mechanical support (711), wherein the mechanical support may be, for example, a silicon wafer.

The MCLED further comprises an interfacial mirror acting as the second mirror (705) for the MCLED micro-cavity. The second mirror (705) may also comprise a GaN/air interface, GaN/epoxy interface or any interfacial material which would expand the extraction cone of the MCLED and enable even higher extraction efficiency, at the second mirror end of the cavity. The n-type contact (706) may be a highly reflective metal, such as silver, acting as the second mirror (705).

The p-GaN (702) thickness locates the active region on an anti-node of the standing optical wave. The nitride based active region (703) is less than λ/4n (where n is refractive index of the active region) thick to allow for the entire active region to be located at an anti-node of a standing wave within the micro-cavity.

The MCLED of FIG. 7 may further comprise a single distributed Bragg reflector as the first mirror (704) or second mirror (705), a transparent contact and photonic crystals fabricated around the MCLED to further improve extraction efficiency. The structure may also be flipped, such that the current confinement layer (707), aperture (708) and highly reflective mirror (704) are deposited on the n-GaN layer (701).

The key feature of this invention is the ability to fabricate and operate a current injected MCLED that has been thinned to a “resonant” thickness within the micro-cavity regime. In an exemplary device, the emission wavelength was 498 nm and the index of refraction of GaN at 498 nm is approximately n=2.4. These values yield a maximum cavity length of approximately 1175 nm in order to be in the micro-cavity regime. The cavity length, or resonant thickness (712) of this exemplary device is approximately 800 nm, verified by profilometry, scanning electron microscopy, and computer modeling of the emission pattern. At this wavelength and cavity length, the MCLED is determined to be roughly in resonance, and is slightly detuned. For this example, z_{AR} (713) is approximately 250 nm.

Micro-cavity operation was evidenced by variations in the emission spectrum with respect to angle and spectral narrowing of the quantum well emission. By comparing the separation of the cavity modes in the emission spectra at different angles a cavity length of approximately 800 nm can be calculated and micro-cavity operation can be verified.

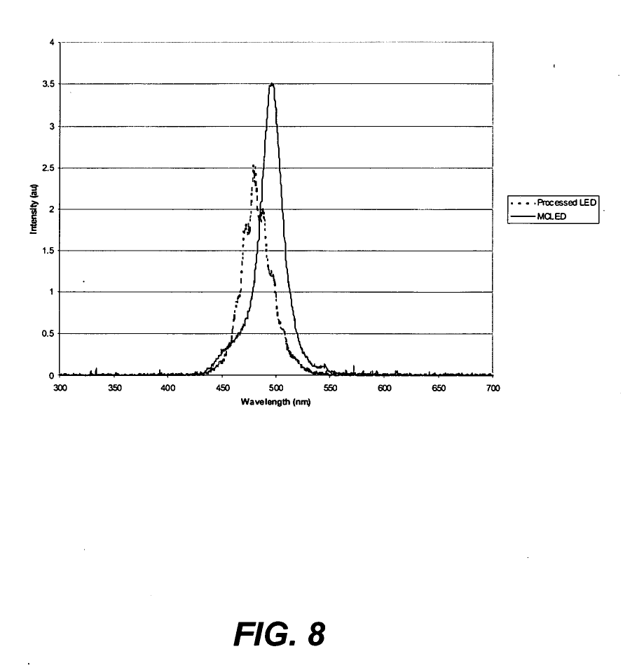

Evidence of spectral narrowing of the emission by the MCLED device was also collected, as shown in FIG. 8. Emission spectra for the MCLED material were collected for a processed MCLED and for a processed standard LED. The emission spectrum for the processed LED shows a wavelength peak at 480 nm and a full width at half maximum (fwhm) of the spectrum of 28 nm. The emission spectrum of the MCLED shows a peak wavelength of 497 nm and a full width at half maximum (fwhm) of the spectrum of 23 nm. The narrowing of the emission indicates the presence of a cavity and the extent of the narrowing corresponds to the calculated values for the device.

Possible Modifications and Variations

Several modifications and variations that incorporate the essential elements of the present invention are outlined below. Additionally, several alternative materials, growth conditions and techniques may be used in practice of this invention, as shall be enumerated below. Any modifications or variations could be used in combination.

1. The growth structure of FIG. 5 and the MCLED of FIG. 7 with any of the following variations or combination of variations to the active region:
a. Single quantum well or multiple quantum well active region with any thickness quantum wells and barriers as long as the active region can be localized to an anti-node of the standing optical wave.
b. A compound active region consisting of localized active regions located on adjacent anti-nodes of the standing optical wave.
c. Any indium containing quantum well.
d. Any aluminum containing quantum well.
e. GaN quantum well for UV emission.
f. Indium containing quantum well barriers.
g. Aluminum containing quantum well barriers.

2. The epitaxial crystal material of FIG. 5 grown on any non-sapphire substrate.

3. The epitaxial crystal material of FIG. 5 grown in a non c-plane crystal orientation.

4. The growth structure of FIG. 5 without an AlGaN capping layer or with a modified AlGaN capping layer (505).

5. The growth structure of FIG. 5 without the unintentionally doped layer and with a thicker Si doped layer.

6. The epitaxial crystal material of FIG. 5 grown on a GaN substrate a GaN template.

7. The growth structure of FIG. 5 grown by another crystal growth method, such as HVPE or MBE.

8. The growth structure of FIG. 5 doped with other dopants that will maintain the p-n junction of the structure.

9. The processing method of FIG. 6 with an alternative current confinement scheme, such as ion implantation.

10. The processing method of FIG. 6 with no current confinement scheme.

11. The processing method of FIG. 6 with any alternative current confinement scheme.

12. The MCLED of FIG. 7 or FIG. 2 with any resonant cavity length within the micro-cavity regime.

13. The growth structure of FIG. 5 and the MCLED of FIG. 7 with any p-type GaN thickness that locates the active region on an anti-node of the standing optical wave as long as the thickness of the cavity is such that the device is operating in the micro-cavity regime.

14. The MCLED of FIG. 2 or FIG. 7 with any detuned or non-detuned resonant cavity length within the micro-cavity regime.

15. The MCLED of FIG. 7 or FIG. 2 with a single distributed Bragg reflectors to define the cavity in place of the silver mirror or interfacial mirror.

16. The MCLED of FIG. 7 with a transparent contact on the surface.

17. The contacts of FIG. 6 fabricated with other metal deposition techniques.

18. The MCLED fabricated using the method of FIG. 6 with a different sub-mount wafer in place of the silicon wafer.

19. The growth structure of FIG. 5 with photonic crystals fabricated around the device to further improve extraction efficiency.

20. The cavity thinning/etch process of FIG. 6 that currently uses reactive ion etching may be performed by inductively coupled plasma etching, photo-electrochemical etching, chemical etching, or mechanical polishing, in order to reduce the cavity thickness.

21. Silver mirrors were used to define the one side of the cavity in FIG. 7 and FIG. 6, but there are many other highly reflective mirror options. Any highly reflective metal mirror that makes a good contact with the p-doped GaN may be used for the mirror contact.

22. Laser lift off for removal of the sapphire is used in FIG. 6, but other sapphire removal techniques exist that may be used. The sapphire may be etched away with a reactive ion etch, or it may be etched away with a laser assisted wet etch, or it could be removed by mechanical polishing.

23. In FIG. 7, the second mirror is defined by the GaN/Air interface, however, the second mirror may also be defined by a GaN/epoxy interface or any interfacial material which would expand the extraction cone of device and enable even higher extraction efficiency.

24. The MCLED of FIG. 7 or FIG. 2 could be fabricated to emit light at any wavelength within the range of the nitride based materials. The design of the growth material in FIG. 5 would have to be modified to account for changes in the wavelength and index of refraction in order to maintain the conditions for resonance.

25. FIG. 6 defines mesas to isolate the device from each other and from the solder metals. Other isolation techniques could be used within the preferred embodiment of FIG. 6.

Advantages and Improvements

The advantages and improvements over existing practice, and the features believed to be new include the following:

1. This is the first time that a micro-cavity LED has been fabricated in the GaN material system.

2. The GaN based micro-cavity LED exhibits superior efficiency over a standard LEDs and resonant cavity LEDs that are not within the micro-cavity regime. The gain in efficiency stem from gains in extraction efficiency.

3. The GaN based micro-cavity LED exhibits superior directionality compared to standard LEDs and resonant cavity LEDs that are not within the micro-cavity regime.

4. Chemical mechanical polishing of the surface of the MCLED device permits well defined cavity modes in the micro-cavity regime which allows for enhanced extraction efficiency.

5. Thin active regions (less than λ/4n, where n is refractive index at wavelength λ) allow for the entire active region to be located at an anti-node (peak) of the standing wave within the cavity, thus ensuring that all of the quantum wells of the device are contributing to the light emission and thereby enhancing the efficiency of the device.

6. Locating the thin active region onto a peak of the standing optical wave ensures that the emission from the active region is resonant with the cavity.

### REFERENCES

The following references are incorporated by reference herein:
1. U.S. Pat. No. 5,226,053, issued Jul. 6, 1993, to Cho, et al., and entitled Light emitting diode.
2. H. Benisty et al., “Impact of planar microcavity effects on light extraction —Part I: basic concepts and analytical trends,” IEEE Journal of Quantum Electronics, Vol. 34, No. 9, p. 1612, September 1998.
3. Nakamura, S., et. al., “The Blue Laser Diode,” Springer, 1997.
4. Schubert, E. F., “Light Emitting Diodes,” Cambridge, 2003.
5. E. Stefanov et al., “Optimizing the external light extraction of nitride LEDs,” Proceedings of SPIE, Vol. 4776, 2002.
6. T. Fujii et al., “Micro cavity effect in GaN-based light-emitting diodes formed by laser lift-off and etch-back technique,” Japanese Journal of Applied Physics, Vol. 43, No. 3B, pp. L411-L413, 2004.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A micro-cavity light emitting diode (MCLED), comprising:
a spontaneously light emitting nitride-based active region placed within a micro-cavity bounded by a first mirror and a second mirror, wherein the micro-cavity has been thinned to a resonant thickness within a micro-cavity regime.

2. The MCLED of claim 1, further comprising n-type gallium nitride (GaN) and p-type GaN bounded by the first and second mirrors.

3. The MCLED of claim 2, wherein a p-type GaN thickness locates the nitride-based active region on an anti-node of a standing optical wave.

4. The MCLED of claim 2, wherein the first mirror comprises a highly reflective metal mirror at one end of the micro-cavity that makes good electrical contact with the n-GaN and the second mirror comprises an interfacial mirror at another end of the micro-cavity.

5. The MCLED of claim 2, further comprising a current confinement layer deposited on the p-type GaN.

6. The MCLED of claim 2, wherein the p-GaN, n-GaN or nitride-based active region is ion implanted.

7. The MCLED of claim 1, wherein the resonant thickness is a micro-cavity length L_{c} satisfying a resonance requirement approximately equal to an integral multiple of half-wavelengths of light emitted by the nitride based active region, such that:
L_{c}≈m_{c}×λ/2n
where m_{c} is a cavity order defined as an integer multiplied by [2nL_{c}/λ], n is an index of refraction for the nitride-based active region at a wavelength λ

8. The MCLED of claim 7, wherein the micro-cavity length is reduced from the resonance requirement in order to detune the micro-cavity so the micro-cavity is in resonance with emitted light only when the light is emitted at an angle off of normal (90°) and the angle is within a critical angle for light emission for the MCLED.

9. The MCLED of claim 1, wherein the nitride-based active region is placed, with respect to the first or second mirror, at an anti-node of an optical wave within the micro-cavity.

10. The MCLED of claim 1, wherein the nitride-based active region is less than λ/4n thick to allow the active region to be located at an anti-node of a standing wave within the micro-cavity, n is an index of refraction for the nitride-based active region at a wavelength λ

11. The MCLED of claim 1, wherein the nitride-based active region is a compound active region comprised of localized active regions located on adjacent anti-nodes of a standing optical wave.

12. The MCLED of claim 1, wherein the first mirror is a single distributed Bragg reflector.

13. The MCLED of claim 1, wherein the second mirror is a single distributed Bragg reflector.
